(19) United States
(12) Patent Application Publication
(10) Pub. No.: US 2010/0053908 A1
(43) Pub. Date: Mar. 4, 2010

(54) Electric device module

(75) Inventors: Gyu Man Hwang, Yongin (KR); Yun Hwi Park, Yongin (KR); Yun Hee Cho, Hwaseong (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/385,368

(22) Filed: Apr. 6, 2009

(30) Foreign Application Priority Data
Aug. 29, 2008 (KR) 10-2008-0085460

(51) Int. Cl. H05K 1/14; H05K 7/02

(52) U.S. Cl. 361/741

(57) ABSTRACT

There is provided an electric device module including: a housing; a board member fixed to one inner side of the housing and including a plurality of connecting terminals; at least one board adhered to another inner side of the housing by a predetermined adhesive and including a plurality of terminals electrically connected to the plurality of connecting terminals; and a guider guiding a mounting position of the board. In the electric device module, a circuit board is prevented from changing in adhering position due to fluidity of an adhesive but can be adhered at a precise position. Also, an extra amount of the adhesive is prevented from flowing outside the circuit board to thereby enhance accuracy and reliability in terms of terminal connection.

### CROSS-REFERENCE TO RELATED APPLICATIONS

This application claims the priority of Korean Patent Application No. 2008-0085460 filed on Aug. 29, 2008, in the Korean Intellectual Property Office, the disclosure of which is incorporated herein by reference.

### BACKGROUND OF THE INVENTION

1. Field of the Invention

The present invention relates to an electric device module, and more particularly, to an electric device module mounted in an electric device embedded in vehicles.

2. Description of the Related Art

In general, a lighting apparatus mounted in a vehicle or an electric apparatus such as an electronic control unit is equipped with parts for mounting an integration device and a passive device which processes data. As one of these parts, an electric device module is provided by disposing a plurality of circuit boards for mounting devices processing an electric signal inside a housing.

In this electric device module, a plurality of circuit boards for processing a complex signal are mounted inside a housing. The circuit boards have terminals electrically connected together by wire bonding.

However, terminals provided on a circuit board are arranged very compactly and thus unless the circuit boards are fixed at precise positions inside the housing, the terminals may be misconnected or unable to be connected.

Also, the circuit boards are fixed into the housing by an adhesive. But the adhesive generally has fluidity and thus when the adhesive is applied on the circuit board to be adhered to the housing, the adhesive may flow before being dried to thereby misalign the circuit boards. This causes the terminals of the circuit boards to be misconnected or unable to be connected.

Moreover, with the electric device module downsized due to a smaller size of an overall apparatus, the plurality of circuit boards need to be arranged within close proximity to one another. This may cause an extra amount of the adhesive to flow outside the circuit board when the circuit boards are adhered into the housing, thus rendering it impossible to connect the terminals together.

### SUMMARY OF THE INVENTION

An aspect of the present invention provides an electric device module in which a circuit board is prevented from changing in adhering position due to fluidity of an adhesive when the circuit board is adhered into a housing by the adhesive but can be adhered at a precise position, thereby preventing defects during connection of terminals, and also an extra amount of the adhesive is prevented from flowing outside the circuit board to thereby enhance accuracy and reliability in terms of terminal connection.

According to an aspect of the present invention, there is provided an electric device module including: a housing; a board member fixed to one inner side of the housing and including a plurality of connecting terminals; at least one board adhered to another inner side of the housing by a predetermined adhesive and including a plurality of terminals electrically connected to the plurality of connecting terminals; and a guider guiding a mounting position of the board.

The guider may be recessed in the another inner side of the housing and include a recess for seating the board therein.

The guider may include: a seating portion provided on the another inner side of the housing; and a seating guide portion provided in a diagonal direction from the seating portion, the seating guide portion projected upward so as to have a corner of the board seated thereon.

The board may include a plurality of boards, and the guider may include: a seating portion provided on the another inner side of the housing; a seating guide portion provided on a corner of the seating portion and protruded upward so as to have a corner of the seating portion seated thereon; a double guide portion provided in a diagonal direction from the seating guide portion, the double guide portion protruded upward so as to have a corner of each of the boards seated thereon.

The seating guide portion may include an accommodating groove providing a predetermined space for accommodating an extra amount of an adhesive between the board and the seating portion.

The seating guide portion may include an accommodating groove providing a predetermined space for accommodating an extra amount of an adhesive between the board and the seating portion, and the double guide portion includes a plurality of accommodating grooves formed in the boards, respectively to be guided so as to accommodate an extra amount of an adhesive between the boards and the seating portion.

The electric device module may further include a flow prevention part preventing an extra amount of an adhesive applied on a bottom end of the board from flowing toward the board member when the board is adhered inside the housing.

The electric device module may further include at least one groove formed in a bottom surface of the recess to accommodate an extra amount of an adhesive applied on a bottom end of the board.

The electric device module may further include at least one channel formed between the seating portion where the board is seated and the board member to accommodate an extra amount of an adhesive applied on a bottom end of the board.

The electric device module may further include a flow path formed on a bottom surface of the seating portion to accommodate an extra amount of an adhesive applied on a bottom end of the board.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating an electric device module according to an exemplary embodiment of the invention;

FIG. 2 illustrates a I-I cross-section of FIG. 1;

FIG. 3 is a perspective view illustrating an electric device module according to another exemplary embodiment of the invention;

FIG. 4 illustrates a II-II cross-section of FIG. 3; and

FIG. 5 is a perspective view illustrating an electric device module according to still another exemplary embodiment of the invention.

### DETAILED DESCRIPTION OF THE PREFERRED EMBODIMENT

Exemplary embodiments of the present invention will now be described in detail with reference to the accompanying drawings.

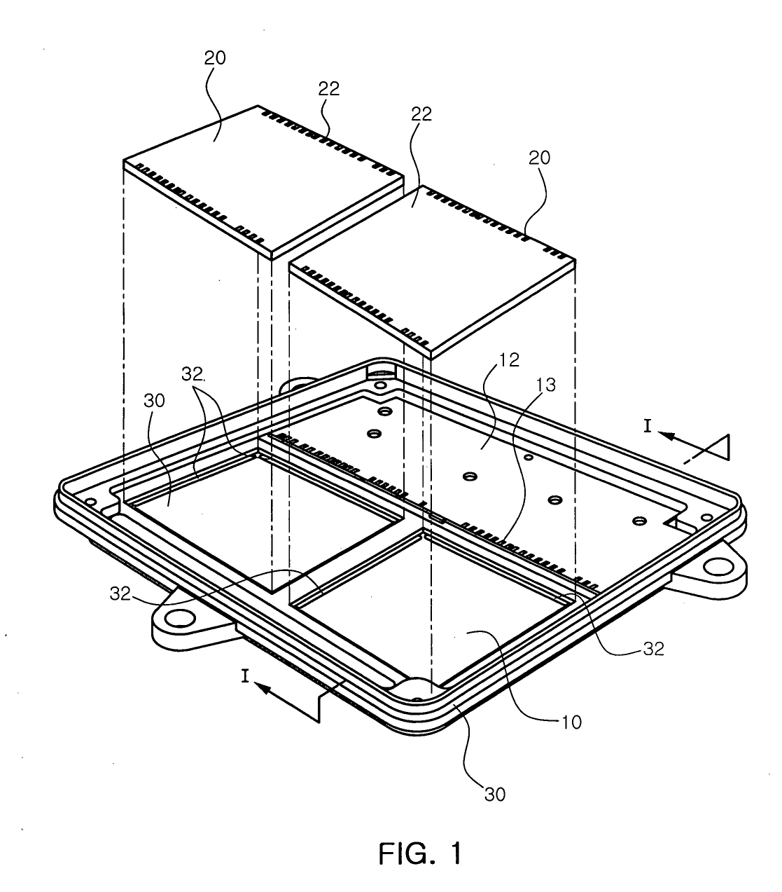

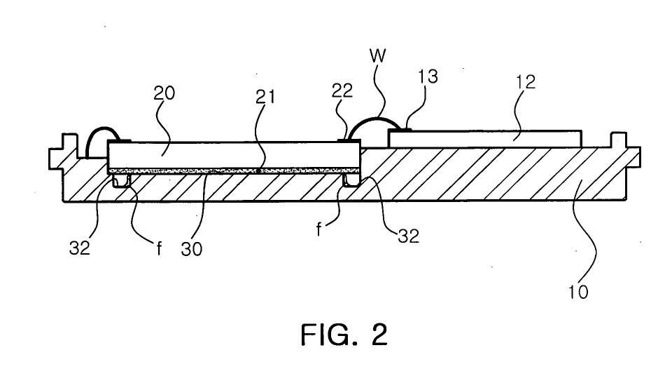

First, an electric device module will be described with reference to FIGS. 1 and 2 according to an exemplary embodiment of the invention. FIG. 1 is a perspective view illustrating an electric device module according to an exemplary embodiment of the invention. FIG. 2 illustrates a I-I cross-section of FIG. 1.

As shown in FIGS. 1 and 2, the electric device module of the present embodiment includes a housing 10, a board member 12 fixed to one inner side of the housing 10 and a board 20 fixed to another inner side of the housing 10.

The housing 10 may be made of a material such as metal, plastic and ceramic. The housing 10 may be made of a metal material to ensure the board 20 is grounded. In a case where the housing 10 is formed of plastic or ceramic, a metal portion may be provide in the housing 10 to ensure the board 20 is grounded.

The housing 10 has a recess 30 formed therein, which serve as a guider. The recess 30 is formed adjacent to the board member 12 and guides a fixing position of the board so that the board 20 is fixedly adhered at a precise position.

The recess 30 is recessed in a bottom surface of the housing 10. The recess 30 may be formed in a substantially identical size to the board 20 to ensure that the board 20 is fixedly seated in the recess.

When the board 20 is accommodated in the recess 30, a predetermined adhesive 21, for example, epoxy resin is applied on a bottom end of the board 20 to allow the board 20 to be fixedly accommodated in the recess 30.

As described above, the board 20 seated and fixed in the recess 30 has terminals 22 bonded to connecting terminals 13 of the board member 12 by wires W to be electrically connected together, as shown in FIG. 2.

Here, the recess 30 guides the position of the board 20 accurately and thus, each of the terminals 22 of the board 20 is wire-bonded to each of the connecting terminals 13 of the board member 12 precisely and easily.

Meanwhile, as shown in FIGS. 1 and 2, grooves may be formed in 30 in the recess 30 of the housing 10.

As shown in FIG. 2, the groove 32 provides a predetermined space into which an extra amount f of the adhesive 21 flows and is accommodated.

Therefore, when the board 20 is adhered to the recess 30 by the adhesive 21, the extra amount f of the adhesive 21 does not flow toward the board member 12 to thereby ensure easier wire bonding and reduce a defect ratio.

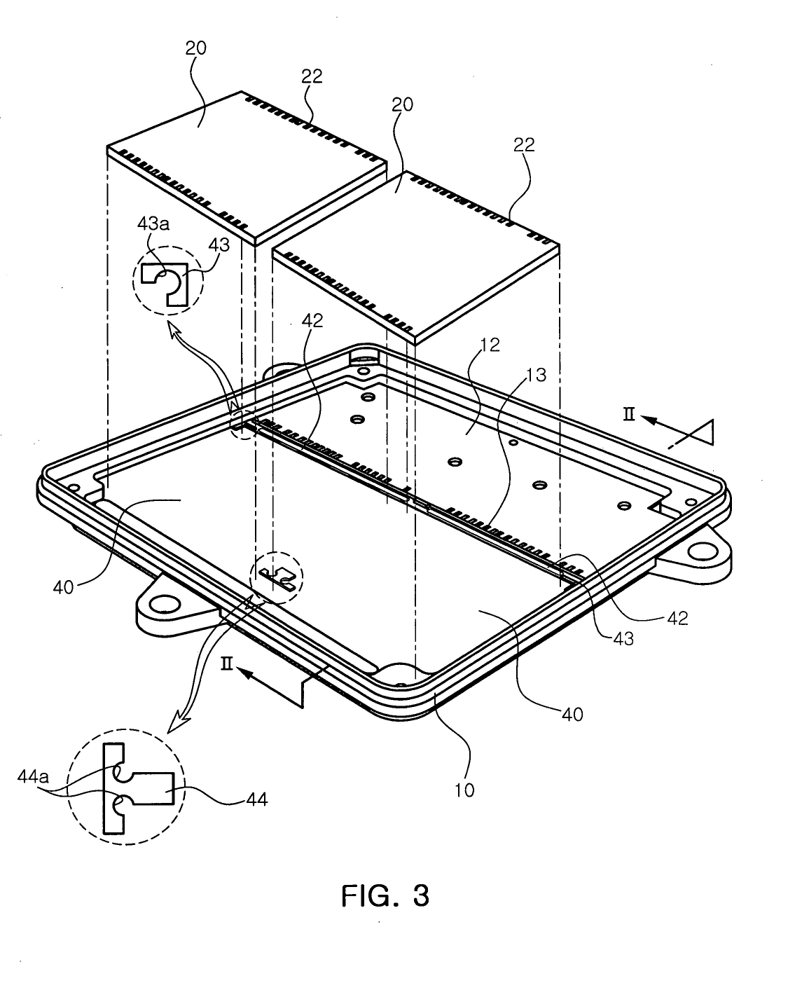

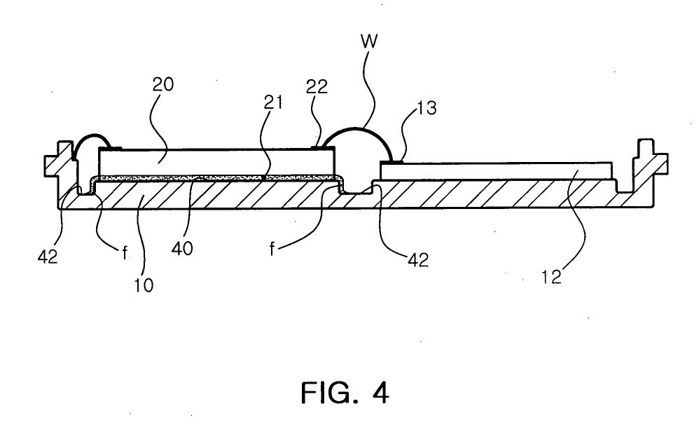

An electric device module according to another exemplary embodiment of the invention will be described with reference to FIGS. 3 and 4. FIG. 3 is a perspective view illustrating an electric device module according to another exemplary embodiment of the invention.

The electric device module of the present embodiment shown in FIGS. 3 and 4 includes a housing 10, a board member 12 and boards 20 in the same manner as the electric device module of the embodiment shown in FIGS. 1 and 2. Also, the electric device of the present embodiment includes a seating guide portion 43 and a double guide portion 44 guiding a location of the board 20.

The seating guide portion 43 and the double guide portion 44 are disposed to face each other in a diagonal direction from the seating portion 40 where the board is seated 20.

The seating guide portion 43 and the double guide portion 44 are shaped as L and T, respectively so that corners of each of the boards 20 are seated thereon.

The seating guide portion 43 and the double guide portion 44 are projected upward from the seating portion 40.

The seating guide portion 43 guides one of the boards 20 to have corners seated thereon. The double guide portion 44 guides two of the boards simultaneously so that corners of the adjacent two boards are seated thereon simultaneously.

Also, the seating guide portion 43 has an accommodating groove 43a formed in an inner side thereof. The accommodating groove 43a provides a predetermined space for accommodating an extra amount of an adhesive when the board 20 is adhered to the seating portion 40 by the adhesive 21.

Moreover, the double guide portion 44 includes two accommodating grooves 44a opposing each other to accommodate the extra amount of the adhesive when the two boards are adhered together.

Meanwhile, as shown in FIGS. 3 and 4, a channel 42 may be elongated along one surface of the board 20 between the seating portion 40 and the board member 12 to provide a predetermined space.

As shown in FIG. 4, the channel 42 provides a predetermined space for accommodating the extra amount f of the adhesive between the board 20 and the seating portion 40. This prevents the extra amount f of the adhesive 21 from flowing toward the board member 12, thereby ensuring easier bonding by wires W and assuring precise and reliable work process.

The channel 42 is provided between the seating portion 40 and the board member 12. Also, as shown in FIG. 4, the channel 42 may be formed at one end of the housing 10.

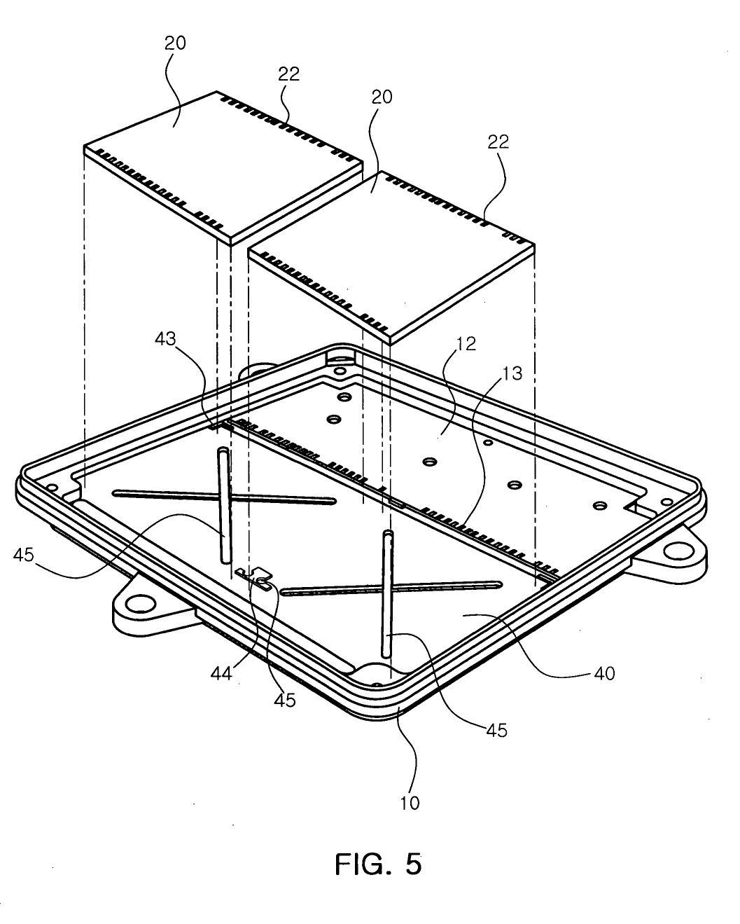

An electric device module will be described according to still another exemplary embodiment of the invention. FIG. 5 is a perspective view illustrating an electric device module according to still another exemplary embodiment of the invention.

The electric device module according to the embodiment shown in FIGS. 1 and 2 includes a groove as a flow prevention part capable of preventing the extra amount of the adhesive from flowing to the board member. The electric device module of the embodiment shown in FIGS. 3 and 4 includes a channel as a flow prevention part capable of preventing the extra amount of the adhesive from flowing toward the board member.

The electric device module of the present embodiment shown in FIG. 5 includes a flow path 45 as a flow prevention part.

The flow path 45 is formed on a bottom surface of a seating portion 40 to provide a predetermined space. The flow path 45 allows the adhesive to flow thereinto when bonding the board 20, thereby preventing an extra amount of the adhesive from flowing outside the board.

The electric device module of the present embodiment shown in FIG. 5 is substantially identical to the embodiments shown in FIGS. 3 and 4 except for the flow prevention part, and thus the other parts will not be described in detail.

Meanwhile, the groove, channel and flow path can be employed alone or in combination as the flow prevention part according to the embodiments.

That is, the flow path of the embodiment shown in FIG. 5 may be employed in place of the groove of the embodiment shown in FIGS. 1 and 2. Also, the flow path and the groove may be utilized at the same time.

Moreover, the channel of the embodiment shown in FIGS. 3 and 4 may be employed in place of or together with the groove of the embodiment shown in FIGS. 1 and 2. The channel may be adopted together with the flow path in the embodiment of FIG. 5.

As set forth above, according to exemplary embodiments of the invention, in an electric device module, a circuit board is prevented from changing in adhering location due to fluidity of an adhesive when the circuit board is adhered into a housing by the adhesive to ensure the circuit board is adhered at a precise position, thereby preventing defects during connection of terminals, and also an extra amount of the adhesive is prevented from flowing outside the circuit board to thereby enhance accuracy and reliability in terms of terminal connection.

While the present invention has been shown and described in connection with the exemplary embodiments, it will be apparent to those skilled in the art that modifications and variations can be made without departing from the spirit and scope of the invention as defined by the appended claims.

What is claimed is:

1. An electric device module comprising:
a housing;
a board member fixed to one inner side of the housing and including a plurality of connecting terminals;
at least one board adhered to another inner side of the housing by a predetermined adhesive and including a plurality of terminals electrically connected to the plurality of connecting terminals; and
a guider guiding a mounting position of the board.

2. The electric device module of claim 1, wherein the guider is recessed in the another inner side of the housing and including a recess for seating the board therein.

3. The electric device module of claim 1, wherein the guider comprises:
a seating portion provided on the another inner side of the housing; and
a seating guide portion provided in a diagonal direction from the seating portion, the seating guide portion projected upward so as to have a corner of the board seated thereon.

4. The electric device module of claim 1, wherein the board comprises a plurality of boards, and
the guider comprises:
a seating portion provided on the another inner side of the housing;
a seating guide portion provided on a corner of the seating portion and protruded upward so as to have a corner of the seating portion seated thereon;
a double guide portion provided in a diagonal direction from the seating guide portion, the double guide portion protruded upward so as to have a corner of each of the boards seated thereon.

5. The electric device module of claim 3, wherein the seating guide portion comprises an accommodating groove providing a predetermined space for accommodating an extra amount of an adhesive between the board and the seating portion.

6. The electric device module of claim 4, wherein the seating guide portion comprises an accommodating groove providing a predetermined space for accommodating an extra amount of an adhesive between the board and the seating portion, and
the double guide portion includes a plurality of accommodating grooves formed in the boards, respectively to be guided so as to accommodate an extra amount of an adhesive between the boards and the seating portion.

7. The electric device module of claim 1, further comprising a flow prevention part preventing an extra amount of an adhesive applied on a bottom end of the board from flowing toward the board member when the board is adhered inside the housing.

8. The electric device module of claim 2, further comprising at least one groove formed in a bottom surface of the recess to accommodate an extra amount of an adhesive applied on a bottom end of the board.

9. The electric device module of claim 3, further comprising at least one channel formed between the seating portion where the board is seated and the board member to accommodate an extra amount of an adhesive applied on a bottom end of the board.

10. The electric device module of claim 3, further comprising a flow path formed on a bottom surface of the seating portion to accommodate an extra amount of an adhesive applied on a bottom end of the board.
